(19) United States
(12) Patent Application Publication
(10) Pub. No.: US 2026/0231353 A1
(43) Pub. Date: Aug. 6, 2026

(54) USER SERVICEABLE ACTIVE COOLING INLET SCREEN

(71) Applicant: Dell Products L.P., Round Rock, TX (US)

(72) Inventors: Christopher A. Torres, San Marcos, TX (US); Deeder Aurongzeb, Austin, TX (US)

(21) Appl. No.: 19/045,980

(22) Filed: Feb. 5, 2025

(51) Int. Cl. H05K 7/20

(52) U.S. Cl. CPC H05K 7/20181; H05K 7/20145; H05K 7/20209

(57) ABSTRACT

An embodiment includes an information handling system. The information handling system includes a chassis comprising an active cooling inlet, the active cooling inlet comprising a plurality of air intake portions admitting airflow into the chassis. The apparatus includes a screen comprising a plurality of perforations allowing airflow through the screen, wherein each perforation in the plurality of perforations has an area smaller than an area of an air intake portion in the plurality of air intake portions. The apparatus includes a hinge coupling the chassis and the screen, the hinge allowing the screen to be moved. between a closed position and an open position, wherein in the closed position the screen allows airflow through the screen and the active cooling inlet.

### BACKGROUND

### Field of the Disclosure

The disclosure relates generally to an information handling system, and in particular, to a user serviceable active cooling inlet screen.

### DESCRIPTION OF THE RELATED ART

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

Innovative aspects of the subject matter described in this specification may be embodied in an information handling system comprising: a chassis comprising an active cooling inlet, the active cooling inlet comprising a plurality of air intake portions admitting airflow into the chassis; a screen comprising a plurality of perforations allowing airflow through the screen, wherein each perforation in the plurality of perforations has an area smaller than an area of an air intake portion in the plurality of air intake portions; and a hinge coupling the chassis and the screen, the hinge allowing the screen to be moved. between a closed position and an open position, wherein in the closed position the screen allows airflow through the screen and the active cooling inlet.

Other embodiments of these aspects include an information handling system comprising: a screen comprising a plurality of perforations allowing airflow through the screen, wherein each perforation in the plurality of perforations has an area smaller than an area of an air intake portion of an active cooling inlet admitting airflow into a chassis; and a hinge coupled to the screen, the hinge allowing the screen to be moved between a closed position and an open position, wherein in the closed position the screen allows airflow through the screen and the active cooling inlet.

Other embodiments of these aspects include a method providing elements of the apparatus.

Particular implementations of the subject matter described in this specification can be implemented so as to realize one or more of the following advantages. For example, providing a user serviceable active cooling inlet screen for a computer system chassis enables a computer user to remove dust and other airflow-impeding particulates from an active cooling inlet screen without having to disassemble the chassis or otherwise risk damage to components within the chassis.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates two example positions of a user serviceable active cooling inlet screen, in accordance with an illustrative embodiment.

FIG. 3 depicts an exploded view of an example configuration for a user serviceable active cooling inlet screen, in accordance with an illustrative embodiment.

FIG. 4 depicts an exploded view of a user serviceable active cooling inlet screen, in accordance with an illustrative embodiment.

FIG. 5 depicts an interior view of a chassis and active cooling inlet screen for use with a user serviceable active cooling inlet screen, in accordance with an illustrative embodiment.

FIG. 6 depicts a flowchart of an example process for a user serviceable active cooling inlet screen. in accordance with an illustrative embodiment.

### DESCRIPTION OF PARTICULAR EMBODIMENTS

Information handling systems such as computer systems typically include an active cooling mechanism such as a fan. The fan moves airflow into a computer system chassis via one or more active cooling inlets, across computer system components such as a processor or memory, and out of the chassis, removing hot air from the chassis and thus cooling the interior of the computer system. To prevent dust and other particulates from entering the chassis with the air, a screen is typically disposed between an active cooling inlet and the outside. However, the dust and other particulates prevented from entering the chassis can accumulate on the screen, impeding airflow into the chassis and thus active cooling efficiency. Thus, there is a need to periodically remove dust and other particulate matter from the screen.

However, cleaning a presently available chassis screen requires disassembly of the chassis to access the screen. Once the screen is accessible, cleaning the screen (e.g., with compressed air) forces particulates across a computer system’s circuit board, potentially damaging components on the circuit board and resulting in unreliable system operation and shortening a system’s lifespan. As well, disassembling and reassembling a computer system chassis, particularly in comparatively small chassis form factors such as used for portable devices, is typically too complicated for a system user, requiring use of a skilled technician at additional cost and time. Thus, the illustrative embodiments recognize that there is a need for a user serviceable active cooling inlet screen, that does not require disassembly and reassembly of a computer system chassis or forcing particulates across a computer system’s circuit board.

This disclosure discusses an apparatus and methods implementing a user serviceable active cooling inlet screen of an information handling system. In particular, an embodiment includes an information handling system comprising a chassis comprising an active cooling inlet, the active cooling inlet comprising a plurality of air intake portions admitting airflow into the chassis; a screen comprising a plurality of perforations allowing airflow through the screen, wherein each perforation in the plurality of perforations has an area smaller than an area of an air intake portion in the plurality of air intake portions; and a hinge coupling the chassis and the screen, the hinge allowing the screen to be moved between a closed position and an open position, wherein in the closed position the screen allows airflow through the screen and the active cooling inlet.

An embodiment includes a chassis. In embodiments, the chassis includes an active cooling inlet. The active cooling inlet includes one or more air intake portions admitting airflow into the chassis. In some embodiments, the chassis at least partially encloses a computer system cooled using airflow admitted into the chassis via the active cooling inlet. In some embodiments, a fan moves airflow into a computer system chassis via one or more active cooling inlets, across computer system components such as a processor or memory, and out of the chassis, removing hot air from the chassis and thus cooling the interior of the computer system. In some embodiments, a bottom, side, or top portion of the chassis includes the active cooling inlet.

An embodiment includes a screen including a plurality of perforations allowing airflow through the screen. Each perforation has an area smaller than an area of an air intake portion of the active cooling inlet. In some embodiments, the perforations are formed by laser perforation, electroforming, or another presently available technique. In some embodiments, the perforations have a substantially circular cross-section. In some embodiments, each perforation has a diameter between approximately 0.5 millimeters and approximately 0.8 millimeters.

An embodiment includes a hinge coupling the chassis and the screen. The hinge is configured to allow the screen to be moved between a closed position and an open position. In the closed position the screen covers the active cooling inlet and allows airflow through the screen and the active cooling inlet into the chassis. In the open position the screen is rotated along a screen edge away from the active cooling inlet, allowing a user to clean both sides of the screen (e.g., with compressed air, a swab, or a cleaning cloth) without directing dust and other particulates into the chassis. In some embodiments, the hinge is formed from a rubber material. In some embodiments, the hinge is coupled to an indentation (e.g., a slot) of the chassis, so as to maintain the screen in the closed position without protruding from an outside surface of the chassis. In some embodiments, the hinge is coupled to the screen using a hook bonded to an inside surface of the screen (i.e., the surface closest to the chassis when the screen is in the closed position). In some embodiments, the hook is a pivot latch, a presently available technique. When the screen is moved to the open position for cleaning, the hook disengages from the chassis and the hinge can be pulled out slightly to give the user additional movement to the open position to provide more room to clean the screen.

A closure maintains the screen in the closed position. In some embodiments, the closure is disposed at an opposite edge from the hinge, so that both the hook (coupled to the hinge) and the closure maintain the screen in the closed position. In some embodiments, the closure includes a first magnetic portion coupled to the screen and a second magnetic portion coupled to the chassis. The first and second magnetic portions are positioned to abut each other when the screen is in the closed position, maintaining the screen in the closed position using magnetic attraction between the two magnetic portions. In some embodiments, the second magnetic portion is coupled to an inside surface of the chassis, so as to maintain the screen in the closed position without protruding from an outside surface of the chassis. In some embodiments, the first and second magnetic portions include a magnetizable material (e.g., sheet metal or steel) and a non-magnetizable material (e.g., plastic). In some embodiments, a magnet-to-ferrous material interface is used instead of a magnet to magnet interface. In other embodiments, the closure includes a first portion coupled to the screen and a second portion coupled to the chassis, and the two portions snap together using a presently available technique to maintain the screen in the closed position. In some embodiments, multiple closures are used to maintain the screen in the closed position without undulations or other undesired openings between the screen and active cooling inlet. In some embodiments, the number of closures depends on the size of the screen and active cooling inlet. For example, a laptop device with an 11 inch display might use two closures, while a laptop with a 17 inch display might use four or five closures.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

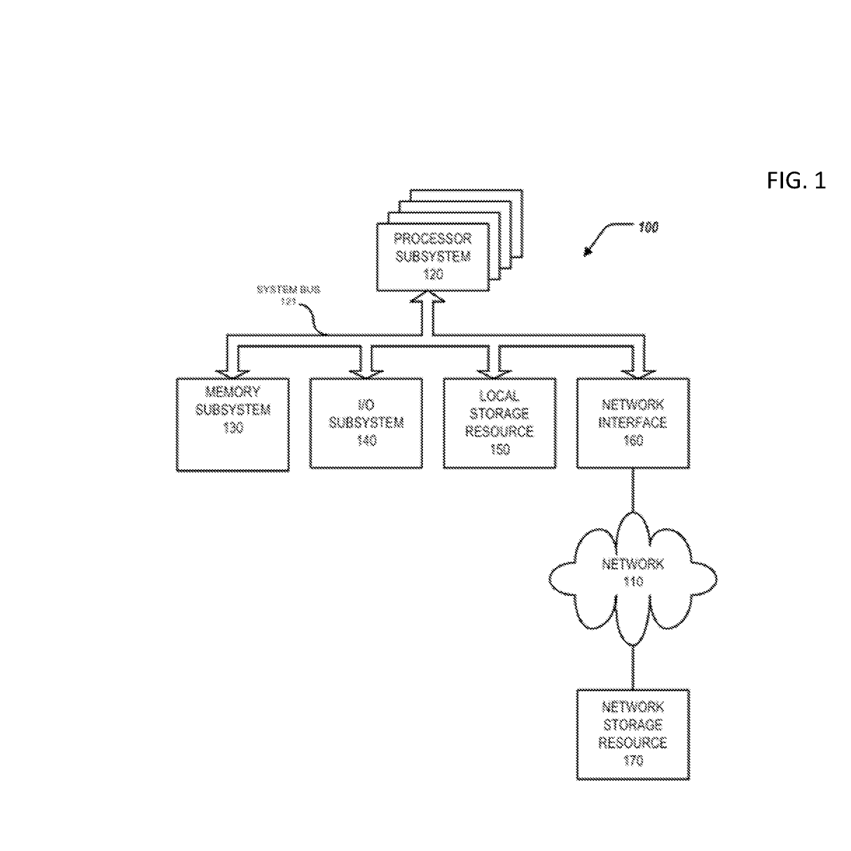

Particular embodiments are best understood by reference to FIGS. 1-5 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

The information handling system 100 can also include a software application. The software application can be included by the memory subsystem 130. The software application can include a computer-executable program (software). The software application can be executed by the processor subsystem 120.

The information handling system 100 can also include a second software application implementing embedded controller functionality. The second software application can be in communication with the processor subsystem 120 or included in the processor subsystem 120. In some examples, the second software application is included by an embedded controller (EC) of the information handling system 100. In some examples, the second software application is included by baseband management controller of the information handling system 100.

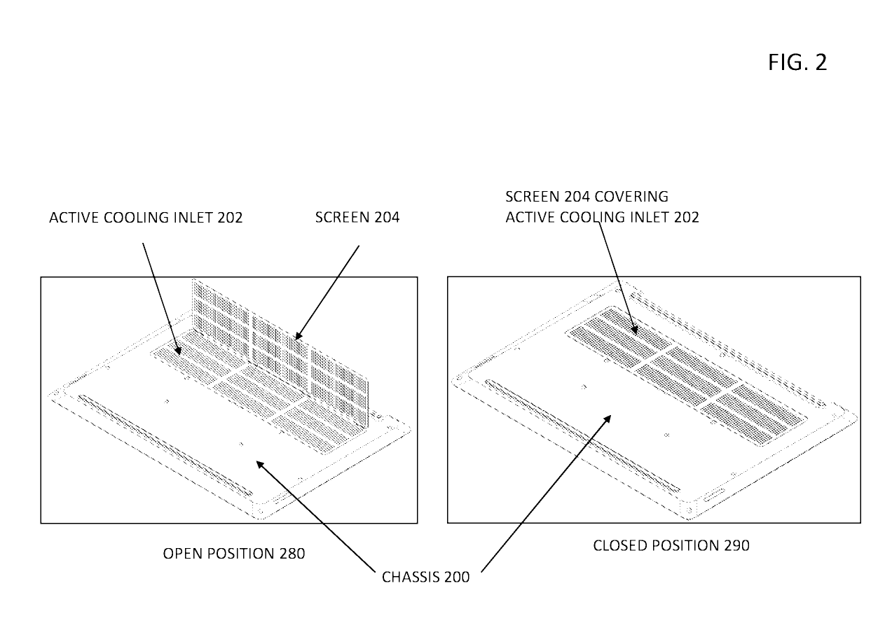

FIG. 2 illustrates two example positions of a user serviceable active cooling inlet screen, in accordance with an illustrative embodiment. The user serviceable active cooling inlet screen can be installed in information handling system 100 in FIG. 1.

Chassis 200 includes active cooling inlet 202. Chassis 200 at least partially encloses a computer system cooled using airflow admitted into chassis 200 via active cooling inlet 202. In some implementations, a fan (not shown) moves airflow into chassis 200 via active cooling inlet 202, across computer system components such as a processor or memory, and out of chassis 200, removing hot air from chassis 200 and thus cooling the interior of the computer system. As depicted in FIG. 2, a bottom surface of chassis 200 includes active cooling inlet 202. In other implementations another surface of chassis 200 includes active cooling inlet 202.

Screen 204 includes a plurality of perforations allowing airflow through screen 204. Each perforation has an area smaller than an area of an air intake portion of active cooling inlet 204. In some implementations, the perforations are formed by laser perforation, electroforming, or another presently available technique. In some implementations, the perforations have a substantially circular cross-section. In some embodiments, each perforation has a diameter between approximately 0.5 millimeters and approximately 0.8 millimeters.

Screen 204 is movable between closed position 290 and open position 280. In closed position 290, as depicted, screen 204 covers active cooling inlet 202 and allows airflow through screen 204 and active cooling inlet 202 into chassis 200. In open position 280 screen 204 is rotated along a screen edge away from active cooling inlet 202, allowing a user to clean both sides of screen 204 (e.g., with compressed air, a swab, or a cleaning cloth) without directing dust and other particulates into chassis 200. Note that while screen 204 is depicted in the open position at an angle of approximately ninety degrees from active cooling inlet 202, other angles for the open position are also possible.

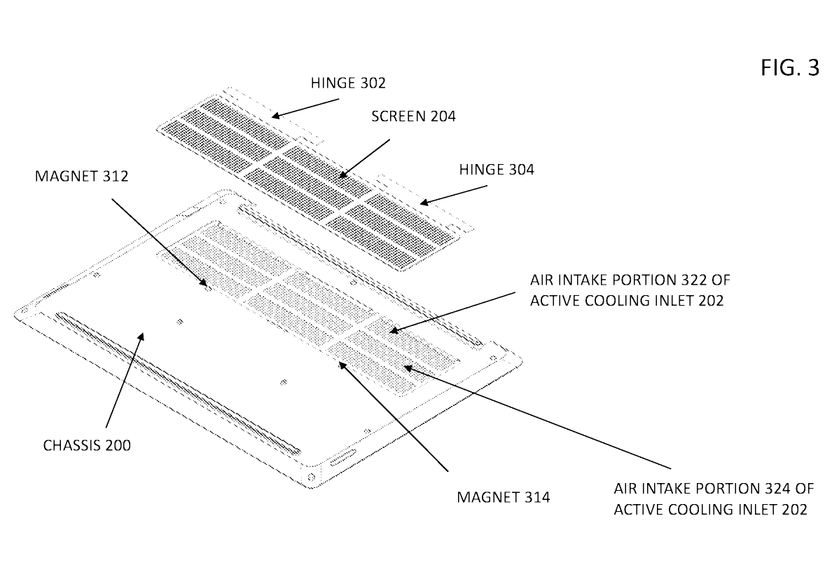

FIG. 3 depicts an exploded view of an example configuration for a user serviceable active cooling inlet screen, in accordance with an illustrative embodiment. Chassis 200, active cooling inlet 202, and screen 204 are the same as chassis 200, active cooling inlet 202, and screen 204 in FIG. 2.

At least one of hinges 302 and 304 couples chassis 200 and screen 204 together. Hinges 302 and 304 are configured to allow screen 204 to be moved between a closed position and an open position. In the closed position screen 204 covers active cooling inlet 202 and allows airflow through screen 204 and active cooling inlet 202 into chassis 200.

Active cooling inlet 202 includes one or more air intake portions (e.g., air intake portions 322 and 324) admitting airflow into chassis 200.

A closure maintains screen 204 in the closed position. In some embodiments, the closure includes a first magnetic portion (not shown) coupled to screen 204 and a second magnetic portion (e.g., magnets 312 and 314) coupled to chassis 200. The first and second magnetic portions are positioned to abut each other when screen 204 is in the closed position, maintaining screen 204 in the closed position using magnetic attraction between the two magnetic portions. In some implementations, the first and second magnetic portions include a magnetizable material (e.g., sheet metal or steel) and a non-magnetizable material (e.g., plastic). In some implementations, a magnet-to-ferrous material interface is used instead of a magnet to magnet interface. In other implementations, magnets 312 and 314 are replaced by a snap-together closure to maintain screen 204 in the closed position. In some embodiments, more or fewer closures than magnets 312 and 314 are used to maintain screen 204 in the closed position without undulations or other undesired openings between screen 204 and active cooling inlet 202. In some implementations, the number of closures depends on the size of the screen and active cooling inlet. For example, a laptop device with an 11 inch display might use two closures, while a laptop with a 17 inch display might use four or five closures.

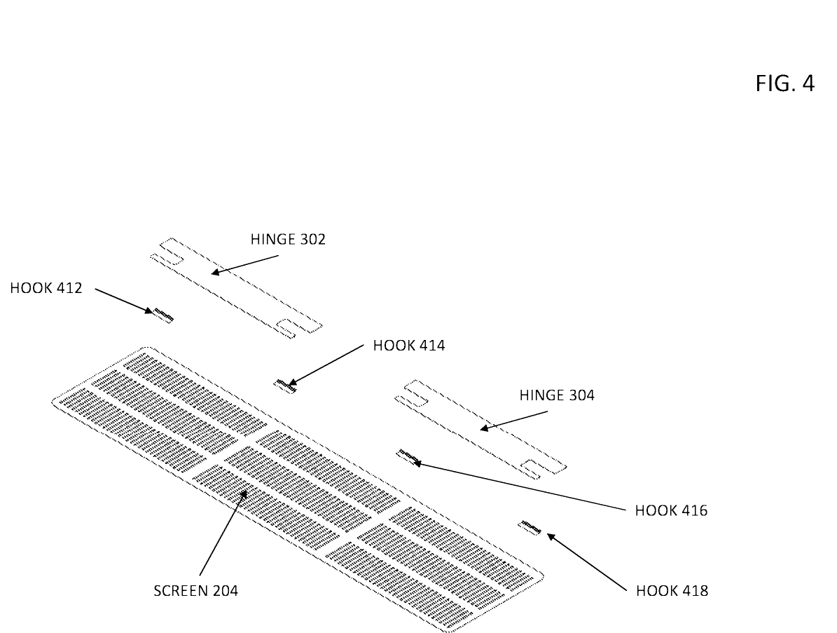

FIG. 4 depicts an exploded view of a user serviceable active cooling inlet screen, in accordance with an illustrative embodiment. Screen 204 is the same as screen 204 in FIG. 2. Hinges 302 and 304 are the same as hinges 302 and 304 in FIG. 3.

In some implementations, hinges 302 and 304 are formed from a rubber material. In some embodiments, hinges 302 and 304 are coupled to an indentation (e.g., a slot) of chassis 202 (not shown), so as to maintain screen 204 in the closed position without protruding from an outside surface of chassis 200. In some embodiments, hinges 302 and 304 are coupled to the screen using one or more hooks (e.g., hooks 412, 414, 416, and 418) bonded to an inside surface of screen 204 (i.e., the surface closest to chassis 200 when screen 204 is in the closed position). In some implementations, hooks 412, 414, 416, and 418 are pivot latches. When screen 204 is moved to the open position for cleaning, hooks 412, 414, 416, and 418 disengage from the chassis and the hinges 302 and 304 can be pulled out slightly to give the user additional movement to the open position to provide more room to clean screen 204.

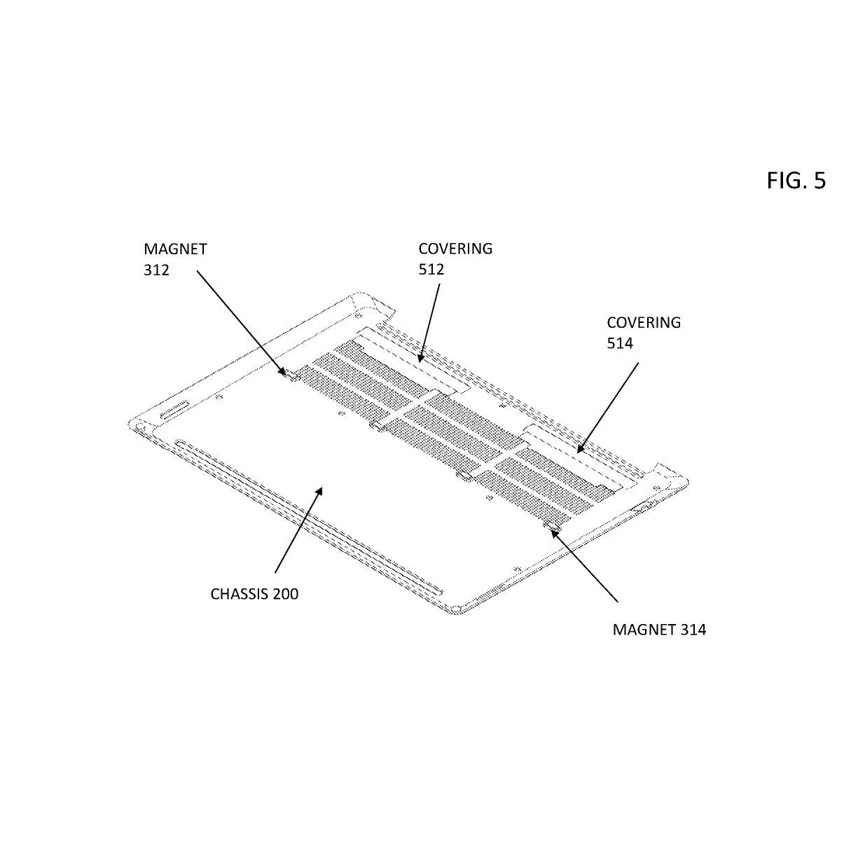

FIG. 5 depicts an interior view of a chassis and active cooling inlet screen for use with a user serviceable active cooling inlet screen. in accordance with an illustrative embodiment. Chassis 200 is the same as chassis 200 in FIG. 2. Magnets 312 and 314 are the same as magnets 312 and 314 in FIG. 3.

Magnets 312 and 314 are coupled to the depicted inside surface of chassis 200, so as to maintain screen 204 (not shown) in the closed position without protruding from an outside surface of chassis 200. Coverings 512 and 514 cover the slots where hinges 302 and 304 enter chassis 200 and serve to restrict visibility into chassis 200 as well as prevent screen 204 from being pulled out accidentally. In one implementation, coverings 512 and 514 are made of a plastic film such as Mylar. (Mylar is a registered trademark of Dupont Teijin Films US in the United States and other countries.)

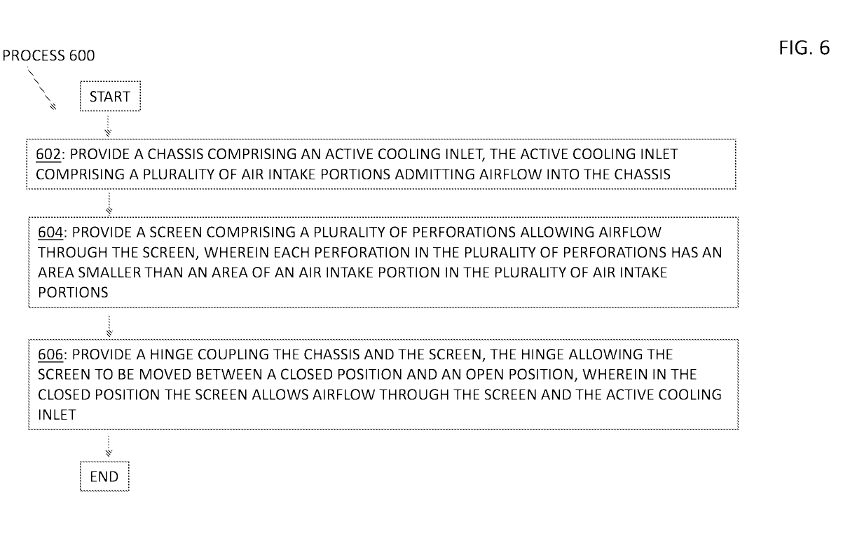

FIG. 6 depicts a flowchart of an example process for a user serviceable active cooling inlet screen. in accordance with an illustrative embodiment.

In block 602 of process 600, the process provides a chassis comprising an active cooling inlet, the active cooling inlet comprising a plurality of air intake portions admitting airflow into the chassis. In block 604, the process provides a screen comprising a plurality of perforations allowing airflow through the screen, wherein each perforation in the plurality of perforations has an area smaller than an area of an air intake portion in the plurality of air intake portions. In block 606, the process provides a hinge coupling the chassis and the screen, the hinge allowing the screen to be moved between a closed position and an open position, wherein in the closed position the screen allows airflow through the screen and the active cooling inlet. Then the process ends.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. An information handling system comprising:
a chassis comprising an active cooling inlet, the active cooling inlet comprising a plurality of air intake portions admitting airflow into the chassis;
a screen comprising a plurality of perforations allowing airflow through the screen, wherein each perforation in the plurality of perforations has an area smaller than an area of an air intake portion in the plurality of air intake portions; and
a hinge coupling the chassis and the screen, the hinge allowing the screen to be moved. between a closed position and an open position, wherein in the closed position the screen allows airflow through the screen and the active cooling inlet.

2. The information handling system of claim 1, wherein the screen covers the active cooling inlet while the screen is in the closed position.

3. The information handling system of claim 1, wherein the screen is rotated along a screen edge away from the active cooling inlet while the screen is in the open position.

4. The information handling system of claim 1, further comprising:
a closure maintaining the screen in the closed position.

5. The information handling system of claim 4, wherein the closure comprises a first magnetic portion coupled to the screen and a second magnetic portion coupled to the chassis, wherein the first magnetic portion and the second magnetic portion are positioned to abut each other when the screen is in the closed position.

6. The information handling system of claim 1, wherein each perforation in the plurality of perforations has a substantially circular cross-section.

7. The information handling system of claim 6, wherein each perforation in the plurality of perforations has a diameter between 0.5 millimeters and 0.8 millimeters.

8. The information handling system of claim 1, wherein the hinge is coupled to the chassis adjacent to the active cooling inlet.

9. The information handling system of claim 1, wherein the hinge is coupled to the screen using a hook, wherein the hook is coupled to an inside surface of the screen.

10. The information handling system of claim 1, wherein the hinge is coupled to a slot portion of the chassis.

11. The information handling system of claim 1, wherein a bottom portion of a computer system cooled using airflow admitted into the chassis via the active cooling inlet comprises the active cooling inlet.

12. An information handling system comprising:
a screen comprising a plurality of perforations allowing airflow through the screen, wherein each perforation in the plurality of perforations has an area smaller than an area of an air intake portion of an active cooling inlet admitting airflow into a chassis; and
a hinge coupled to the screen, the hinge allowing the screen to be moved between a closed position and an open position, wherein in the closed position the screen allows airflow through the screen and the active cooling inlet.

13. The information handling system of claim 12, wherein the screen covers the active cooling inlet while the screen is in the closed position.

14. The information handling system of claim 12, wherein the screen is rotated along a screen edge away from the active cooling inlet while the screen is in the open position.

15. The information handling system of claim 12, further comprising:
a closure maintaining the screen in the closed position.

16. The information handling system of claim 15, wherein the closure comprises a first magnetic portion coupled to the screen and a second magnetic portion coupled to the chassis, wherein the first magnetic portion and the second magnetic portion are positioned to abut each other when the screen is in the closed position.

17. The information handling system of claim 12, wherein each perforation in the plurality of perforations has a substantially circular cross-section.

18. The information handling system of claim 17, wherein each perforation in the plurality of perforations has a diameter between 0.5 millimeters and 0.8 millimeters.

19. The information handling system of claim 12, wherein the hinge is coupled to the screen using a hook, wherein the hook is coupled to an inside surface of the screen.

20. A method, comprising:
providing a chassis comprising an active cooling inlet, the active cooling inlet comprising a plurality of air intake portions admitting airflow into the chassis;
providing a screen comprising a plurality of perforations allowing airflow through the screen, wherein each perforation in the plurality of perforations has an area smaller than an area of an air intake portion in the plurality of air intake portions; and
providing a hinge coupling the chassis and the screen, the hinge allowing the screen to be moved between a closed position and an open position, wherein in the closed position the screen allows airflow through the screen and the active cooling inlet.
